(19) United States
(12) Patent Application Publication
(10) Pub. No.: US 2026/0255852 A1
(43) Pub. Date: Aug. 27, 2026

(54) DISPLAY DEVICE

(71) Applicant: SK hynix Inc., Icheon-si (KR)

(72) Inventor: Young Hwan HYEON, Icheon-si (KR)

(21) Appl. No.: 19/277,074

(22) Filed: Jul. 22, 2025

(30) Foreign Application Priority Data
Feb. 25, 2025 (KR) 10-2025-0024310

(51) Int. Cl. H10K 59/80; H10K 102/00

(52) U.S. Cl. CPC H10K 59/876; H10K 2102/351

(57) ABSTRACT

In an embodiment, a display device includes a substrate including pixel regions for a plurality of sub-pixels configured to emit light in response to an electric signal, wherein the plurality of sub-pixels include a first sub-pixel, a second sub-pixel, and a third sub-pixel; a first reflective electrode disposed on the substrate in the first sub-pixel; a first insulating layer disposed on the first reflective electrode; a second reflective electrode disposed on the first insulating layer in the second sub-pixel; a second insulating layer disposed on the second reflective electrode; and a third reflective electrode disposed on the second insulating layer in the third sub-pixel, in which a thickness of the first reflective electrode is greater than a thickness of the second reflective electrode and a thickness of the third reflective electrode.

### PRIORITY CLAIM AND CROSS REFERENCE TO RELATED APPLICATIONS

This patent document claims the priority and benefits of Korean Patent Application No. 10-2025-0024310 filed on Feb. 25, 2025, which is incorporated by reference in its entirety as part of the disclosure of this patent document.

### TECHNICAL FIELD

The technology and implementations disclosed in this patent document generally relate to a display device.

### BACKGROUND

As the information society continues to develop, there is a growing demand for display devices that can represent images, and various types of display devices, such as liquid crystal displays (LCDs) and organic light emitting diode (OLED) displays are being utilized.

Among these, OLED displays are self-luminous and offer superior viewing angles and contrast ratios compared to LCDs. OLED displays do not require a separate backlight, allowing for lighter and thinner designs, and they have the advantage of low power consumption. In addition, OLED displays can be driven by low direct current voltage, have fast response times, and offer lower manufacturing costs.

Recently, there has been an increasing demand for displays that utilize OLED technology in applications such as augmented reality (AR) and virtual reality (VR), and other devices that require ultra-high resolution at a comparable level.

### SUMMARY

The disclosed technology can be implemented in some embodiments to provide a display device with improved reflectivity of a reflective electrode and uniform reflectivity of the reflective electrode across sub-pixels.

Embodiments of the disclosed technology are not limited to producing a single technical effect. Various technical effects and advantages will become apparent.

In some embodiments, a display device based on an embodiment includes a substrate including pixel regions for a plurality of sub-pixels configured to emit light in response to an electric signal (e.g., a current), wherein the plurality of sub-pixels include a first sub-pixel, a second sub-pixel, and a third sub-pixel; a first reflective electrode disposed on the substrate in the first sub-pixel; a first insulating layer disposed on the first reflective electrode; a second reflective electrode disposed on the first insulating layer in the second sub-pixel; a second insulating layer disposed on the second reflective electrode; and a third reflective electrode disposed on the second insulating layer in the third sub-pixel, in which a thickness of the first reflective electrode is greater than a thickness of the second reflective electrode and a thickness of the third reflective electrode.

In some embodiments, a display device based on an embodiment includes a substrate including pixel regions for a plurality of sub-pixels configured to emit light in response to an electric signal (e.g., a current), wherein the plurality of sub-pixels include a first sub-pixel, a second sub-pixel, and a third sub-pixel; a first reflective electrode disposed on the first sub-pixel; a second reflective electrode disposed on the second sub-pixel; a third reflective electrode disposed on the third sub-pixel; an anode electrode disposed on the first reflective electrode, the second reflective electrode, and the third reflective electrode; a common light-emitting layer disposed on the anode electrode; and a cathode electrode disposed on the common light-emitting layer, in which a distance between the first reflective electrode and the cathode electrode, a distance between the second reflective electrode and the cathode electrode, and a distance between the third reflective electrode and the cathode electrode are different from each other, and at least one of the first reflective electrode, the second reflective electrode, and the third reflective electrode has a different thickness than one or more remaining reflective electrodes.

Specific details of other embodiments are included in the detailed description and drawings.

In some embodiments, the thickness of the first reflective electrode may be greater than the thickness of the second reflective electrode and the third reflective electrode. The first reflective electrode may be positioned below the second reflective electrode and the third reflective electrode. Each of the reflective electrodes has a laminated structure of a first layer (or titanium (Ti)) and a second layer (or aluminum (Al)), and after each of the reflective electrodes is formed, a subsequent thermal process may be performed. In the subsequent thermal process, the titanium (Ti) of each of the reflective electrodes may be diffused toward the aluminum (Al) side to form an alloy with the aluminum (Al). In particular, since the first reflective electrode is formed first, the titanium (Ti) may expand the most, such that the reflectivity of the first reflective electrode may be reduced. Therefore, in some embodiments, by making the thickness of the first reflective electrode (or the thickness of the second layer of the first reflective electrode) larger than the thickness of the remaining reflective electrodes (or the thickness of the second layer of the reflective electrodes), the reduction in the reflectivity of the reflective electrodes may be minimized, and the reflectivity of the reflective electrode of each sub-pixel may be designed to be the same.

### BRIEF DESCRIPTION OF THE DRAWINGS

FIG. 1 is a block diagram showing a display device based on an embodiment.

FIG. 2 is a cross-sectional view of the display panel of FIG. 1.

FIG. 3 is an enlarged view showing a first reflective electrode, a second reflective electrode, and a third reflective electrode, based on an embodiment.

FIGS. 4 to 6 are cross-sectional views showing each process step in a manufacturing process of a display device, based on an embodiment.

FIG. 7 is a drawing showing diffusion of titanium (Ti) due to a subsequent thermal process of a first reflective electrode, a second reflective electrode, and a third reflective electrode, based on an embodiment.

FIG. 8 is a cross-sectional view of a display panel based on another embodiment.

FIG. 9 is an enlarged view showing a first reflective electrode, a second reflective electrode, and a third reflective electrode, based on another embodiment.

FIG. 10 is an enlarged view showing a first reflective electrode, a second reflective electrode, and a third reflective electrode, based on another embodiment.

### DETAILED DESCRIPTION

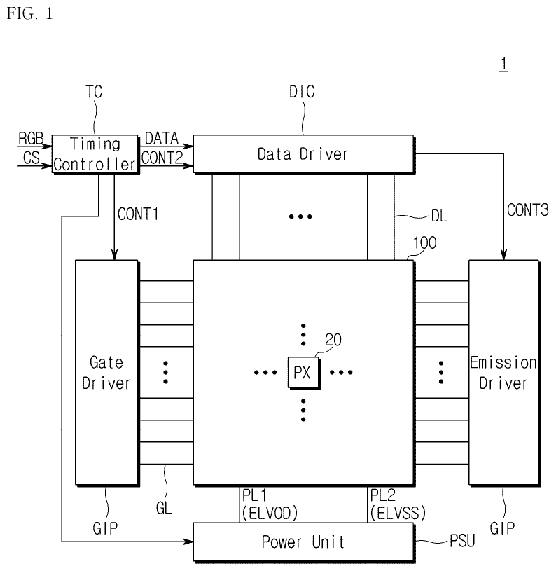

FIG. 1 is a block diagram showing a display device based on an embodiment.

Referring to FIG. 1, the display device 1 includes a timing control unit TC, a gate driver GIP, a data driver DIC, a light emitting driver GIP, a power supply unit PSU, and a display panel 100.

The timing control unit TC may receive an image signal RGB and a control signal CS from an external device such as an external host system. The image signal RGB may include a plurality of grayscale data. The control signal CS may include, for example, a horizontal synchronization signal, a vertical synchronization signal, and a main clock signal.

The timing control unit TC may process the image signal RGB and the control signal CS to match the operating conditions of the display panel 100, and may generate and output image data DATA, a gate drive control signal CONT1, a data drive control signal CONT2, a light-emitting drive control signal CONT3, and a power supply control signal CONT4.

The gate drive control signal CONT1 may include a scan timing control signal, such as a gate start pulse, a gate shift clock, and a gate output enable signal. The data drive control signal CONT2 may include a data timing control signal, such as a source sampling clock, a polarity control signal, and a source output enable signal.

The gate driver GIP may sequentially output, through a gate line GL, gate signals for each horizontal period within one frame in response to the gate drive control signal CONT1 provided by the timing control unit TC. Accordingly, a pixel row connected to each gate line GL is turned on for each horizontal period. During each horizontal period, a data signal may be applied to the pixel row that is turned on by the gate line GL. In some implementations, the term “horizontal period” refers to the time required to drive a single horizontal line, e.g., one row of pixels.

The gate driver GIP may include stage circuits for storing or holding electrical signals or data for a certain period of time. In some implementations, each of the stage circuits is electrically connected to a plurality of gate lines GL. In some implementations, the gate driver GIP may be implemented in the form of a Gate In Panel (GIP) structure mounted on the display panel 100. Such a gate driver GIP may include a shift register, a level shifter, etc.

The data driver DIC converts digital image data DATA, provided by a timing control unit TC, into an analog data signal in response to a data driving control signal CONT2. The data driver DIC may apply the analog data signal to the corresponding panel pixels 20 through a data line DL.

The emission driver GIP may generate emission signals based on an emission driving control signal CONT3 output from the timing control unit TC. The emission driver GIP may provide the generated gate signals to the panel pixels 20 through a plurality of emission lines (EL).

In FIG. 1, although the gate driver and the emission driver are illustrated separately, the gate driver and the emission driver may be integrated into a single unit. Hereinafter, in some embodiments, the gate driver and the emission driver will be collectively referred to as a gate driver GIP.

The power supply unit PSU may convert an externally supplied voltage into a high-level voltage ELVDD and the low-level voltage ELVSS, which serve as standard operating voltages within the display device 1, based on the power supply control signal CONT4. The power supply unit PSU outputs the generated driving voltages ELVDD and ELVSS to various components through power lines PL1 and PL2.

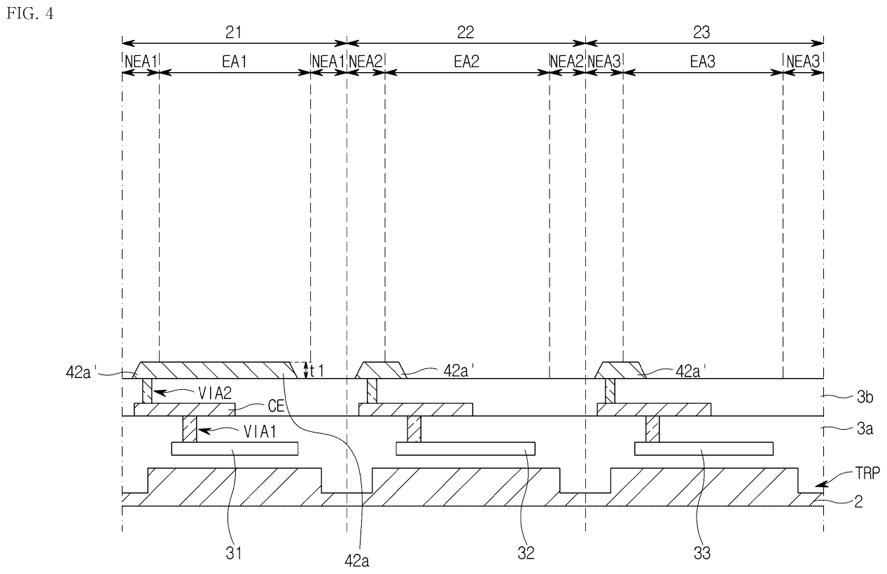

In the display device 1 implemented based on an embodiment, the timing control unit TC, the data driver DIC, the gate driver GIP, and the power supply unit PSU may each be integrated into the display panel 100. In some implementations, the circuits constituting the timing control unit TC, the data driver DIC, the gate driver GIP, and the power supply unit PSU may be formed together during the fabrication process of the display panel 100. The timing control unit TC, data driver DIC, gate driver GIP, and power supply unit PSU may each be mounted on a substrate (see “2” of FIG. 4). In some embodiments, the timing control unit TC, data driver DIC, gate driver GIP, and power supply unit PSU may be implemented as a separate chip CHIP, distinct from the display panel 100.

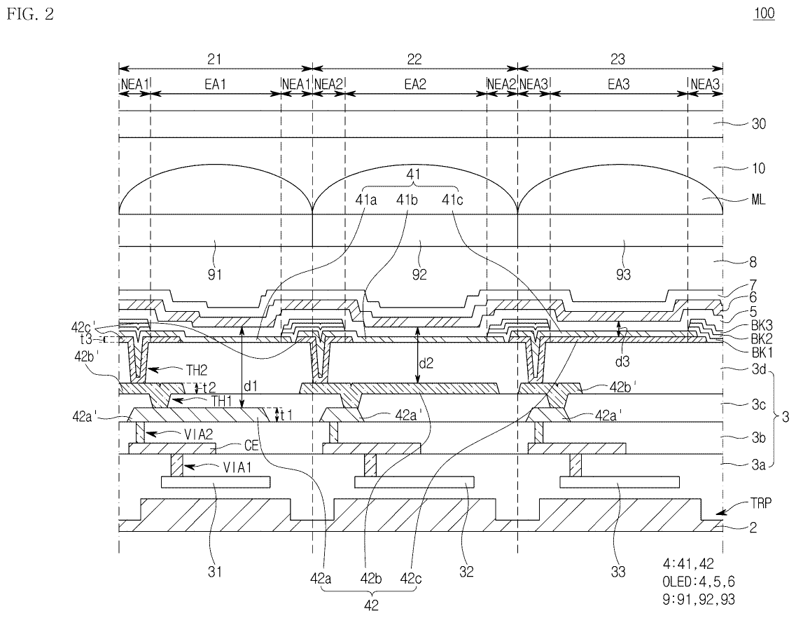

FIG. 2 is a cross-sectional view of the display panel of FIG. 1.

Referring to FIG. 2, a display panel 100 based on an embodiment includes a substrate 2, a first electrode 4, a common light-emitting layer 5, and a second electrode 6. The first electrode 4, the common light-emitting layer 5, and the second electrode 6 may constitute an organic light-emitting device (OLED).

A plurality of sub-pixels 21, 22, and 23 is formed on the substrate 2. The plurality of sub-pixels 21, 22, and 23 may constitute one pixel (see “20” of FIG. 1). A plurality of pixels (see “20” of FIG. 1) may be formed on the substrate 2.

The plurality of sub-pixels 21, 22, and 23 may include a first sub-pixel 21, a second sub-pixel 22, and a third sub-pixel 23. The first sub-pixel 21, the second sub-pixel 22, and the third sub-pixel 23 are sequentially arranged such that the second sub-pixel 22 is positioned adjacent to one side, e.g., the right side, of the first sub-pixel 21, and the third sub-pixel 23 is positioned adjacent to one side, e.g., the right side, of the second sub-pixel 22. In some embodiments, the terms “pixel” or “sub-pixel” can be used to indicate an element of a display device that emits light in response to an electric signal (e.g., a current). In some implementations, each pixel may include a plurality of sub-pixels, such as red, green, and blue (RGB) sub-pixels. In some implementations, each sub-pixel includes an organic emissive layer that emits light of a specific wavelength when an electric signal (e.g., a current) is applied.

The first sub-pixel 21 may be configured to emit red (R) light, the second sub-pixel 22 may be configured to emit green (G) light, and the third sub-pixel 23 may be configured to emit blue (B) light. However, the disclosed technology is not limited thereto.

In FIG. 2, although an example is provided in which the pixel is configured to include only three sub-pixels 21, 22, and 23, the disclosed technology is not limited thereto. In some implementations, the pixel may include four sub-pixels. When the pixel includes four sub-pixels, the pixel may further include a fourth sub-pixel configured to emit white (W) light.

Each of the first to third sub-pixels 21, 22, and 23 may be configured to have the same size. For example, each of the first to third sub-pixels 21, 22, and 23 may be configured to have the same width and the same height.

Each of the sub-pixels 21, 22, and 23 may include a light-emitting area EA1, EA2, and EA3 and a non-light-emitting area NEA1, NEA2, and NEA3. The first sub-pixel 21 may include a first light-emitting area EA1 and a first non-light-emitting area NEA1 that surrounds the first light-emitting area EA1, the second sub-pixel 22 may include a second light-emitting area EA2 and a second non-light-emitting area (NEA2) that surrounds the second light-emitting area EA2, and the third sub-pixel 23 may include a third light-emitting area EA3 and a third non-light-emitting area NEA3 that surrounds the third light-emitting area EA3. Each of the light-emitting areas EA1, EA2, and EA3 may correspond to an area exposed from a bank BK of anode electrodes 41a, 41b, and 41c, as will be described below.

The first electrode 4 is patterned individually for each of the sub-pixels 21, 22, and 23. In some implementations, one first electrode 4 is formed for the first sub-pixel 21, another first electrode 4 is formed for the second sub-pixel 22, and still another first electrode 4 is formed for the third sub-pixel 23. The first electrode 4 may function as an anode of the display panel 100. The first electrode 4 may include a reflective electrode 42 and an anode electrode 41. The anode electrode 41 and the reflective electrode 42 may be arranged for each sub-pixel 21, 22, and 23. The anode electrode 41 may include a first anode electrode 41a disposed in the first sub-pixel 21, a second anode electrode 41b disposed in the second sub-pixel 22, and a third anode electrode 41c disposed in the third sub-pixel 23, and the reflective electrode 42 may include a first reflective electrode 42a disposed in the first sub-pixel 21, a second reflective electrode 42b disposed in the second sub-pixel 22, and a third reflective electrode 42c disposed in the third sub-pixel 23. The reflective electrodes 42a, 42b, and 42c of each sub-pixel 21, 22, and 23 may be positioned at different heights relative to one another. For example, the first reflective electrode 42a may be placed at the lowest level, the second reflective electrode 42b may be placed in an intermediate level, and the third reflective electrode 42c may be placed at the highest level.

A bank BK may be arranged on each of the anode electrodes 41a, 41b, and 41c. The bank BK may cover the edges of the anode electrodes 41a, 41b, and 41c, which are arranged on the first to third sub-pixels 21, 22, and 23, respectively, thereby allowing the first sub-pixel 21, the second sub-pixel 22, and the third sub-pixel 23 to be clearly distinguished from one another.

The display panel 100 may utilize the micro-cavity characteristics by providing the reflective electrodes 42a, 42b, and 42c at different surface heights for each of the sub-pixels 21, 22, and 23, thereby further improving the light extraction efficiency.

The micro-cavity characteristic refers to a phenomenon in which constructive interference occurs (and the light is thus amplified) when the distance between the reflective electrodes 42a, 42b, and 42c and the second electrode 6 is an integer multiple of half the wavelength (λ/2) of the light emitted from the sub-pixels 21, 22, and 23. When the reflection process and re-reflection process are repeated between the reflective electrode 42a, 42b, or 42c and the second electrode 6, the degree of light amplification continuously increases, thereby improving the external light extraction efficiency. Therefore, the distances between the sub-pixels 21, 22, or 23 and their corresponding reflective electrodes 42a, 42b, or 42c may be individually adjusted.

The common light-emitting layer 5 may be configured to emit white light. For example, the common light-emitting layer 5 may be provided with a two-stack structure including a blue light-emitting layer, a yellow-green light-emitting layer, and a charge generation layer, or may be provided with a three-stack structure including a blue light-emitting layer, a green light-emitting layer, a red light-emitting layer, and a charge generation layer, thereby emitting white light, but is not necessarily limited thereto and may be provided with a plurality of layers exceeding three stacks as long as it may emit white light.

The common light-emitting layer 5 may be formed to be provided as a common layer over all of the first to third sub-pixels 21, 22, and 23.

The second electrode 6 may function as a cathode, to form an electric field with the anode electrodes 41a, 41b, and 41c. The second electrode 6 is arranged on the upper surface of the common light-emitting layer 5, which is opposite to the lower surface of the common light-emitting layer 5 with which the anode electrode 41a, 41b, and 41c is in contact, and may be provided as a common layer over all of the first to third sub-pixels 21, 22, and 23.

The second electrode 6 may be provided as a second electrode in the case of a top emission method, whereas it may be provided as a first electrode including a reflective material in the case of a bottom emission method. The second electrode 6 may be formed as a semitransparent electrode to increase light extraction efficiency by utilizing micro-cavity characteristics, in the case of the top emission method. Since the display device 1 increases light extraction efficiency by utilizing micro-cavity characteristics in the top emission method, an example in which the second electrode 6 is formed as a semitransparent electrode will be described.

The color filter layer 9 is provided in each of the first to third sub-pixels 21, 22, and 23 to block a specific color from the light emitted from the common light-emitting layer 5 of each of the sub-pixels 21, 22, or 23. The first color filter 91 provided in the first sub-pixel 21 may be provided to block light of colors other than red (R) light. In this case, the first color filter 91 may be provided as a red color filter. The second color filter 92 provided in the second sub-pixel 22 may be provided to block light of colors other than green (G) light. In this case, the second color filter 92 may be provided as a green color filter. The third color filter 93 provided in the third sub-pixel 23 may be provided to block light of colors other than blue (B) light. In this case, the third color filter 93 may be provided as a blue color filter. However, the embodiments of the disclosed technology are not limited thereto. When a fourth sub-pixel is further included, a white color filter may be further arranged.

The first to third color filters 91, 92, and 93 provided in each of the first to third sub-pixels 21, 22, and 23 may be provided in a size identical to the size of each sub-pixel, or may be provided in such a manner in which they are reduced or enlarged at a certain ratio to the size of each sub-pixel.

Circuit portions 31, 32, and 33 may be arranged in the non-emitting areas NEA1, NEA2, and NEA3 of each of the sub-pixels 21, 22, and 23. Each of the circuit portions 31, 32, and 33 may include a CMOS circuit or a transistor circuit, but the embodiments of the disclosed technology are not limited thereto.

The circuit portions 31, 32, and 33 may at least partially overlap with the reflective electrodes 42a, 42b, and 42c provided in each of the sub-pixels 21, 22, and 23. The circuit portions 31, 32, and 33 may be electrically connected to the reflective electrodes 42a, 42b, and 42c, respectively.

As discussed below, the display panel 100 based on an embodiment may include a laminated structure.

The display device 1 based on an embodiment includes a substrate 2, an insulating layer 3, a first electrode 4, a bank BK, a common light-emitting layer 5, a second electrode 6, a capping layer 7, a sealing layer 8, a color filter layer 9, a micro lens ML, a planarization layer 10, and a cover layer 20.

The substrate 2 may be a plastic film, a glass substrate, or a semiconductor substrate such as silicon. For example, the substrate 2 may be a semiconductor substrate.

The substrate 2 may include a transparent material or an opaque material. A first sub-pixel 21, a second sub-pixel 22, and a third sub-pixel 23 are disposed on the substrate 2. The first sub-pixel 21 may be provided to emit red (R) light, the second sub-pixel 22 may be provided to emit blue (B) light, and the third sub-pixel 23 may be provided to emit green (G) light.

The display device 1 based on an embodiment is formed in a method known as the top emission method in which the emitted light is emitted upward, such that the material of the substrate 2 may be used with not only a transparent material but also an opaque material. The color filters 91, 92, and 93 may be disposed on the upper sides of the first to third sub-pixels 21, 22, and 23 from which the light is emitted, respectively, to transmit light corresponding to each designated color described above.

At least one trench portion TRP may be formed in the substrate 2. In the trench portion TRP, the substrate 2 may be recessed in the thickness direction. The trench portion TRP may be arranged to correspond to the boundary between adjacent sub-pixels 21, 22, and 23. In some embodiments, a plurality of trench portions TRP may be formed within one sub-pixel 21, 22, and 23, but the embodiments of the disclosed technology are not limited thereto. The trench portion TRP may prevent the circuit portions 31, 32, and 33 between adjacent sub-pixels 21, 22, and 23 from conducting through the substrate 2.

The insulating layer 3 is formed on the substrate 2. The insulating layer 3 may include an inorganic insulating material. The insulating layer 3 may include a first insulating layer 3a, a second insulating layer 3b on the first insulating layer 3a, a third insulating layer 3c on the second insulating layer 3b, and a fourth insulating layer 3d on the third insulating layer 3c.

In the insulating layer 3, a plurality of circuit portions 31, 32, and 33, various signal lines, and circuit elements such as capacitors are provided for each of the sub-pixels 21, 22, and 23. The circuit portions 31, 32, and 33 may be arranged in the first insulating layer 3a. The signal lines may include gate lines, data lines, power lines, and reference lines, and the circuit portions 31, 32, and 33 may include CMOS circuits or thin film transistors. When the circuit portions 31, 32, and 33 include a thin film transistor, the thin film transistor may be configured to include a switching thin film transistor, a driving thin film transistor, and a sensing thin film transistor. The switching thin film transistor is switched depending on a gate signal supplied to the gate line and serves to transmit the data voltage from the data line to the driving thin film transistor.

The driving thin film transistor is switched depending on the data voltage from the switching thin film transistor and serves to generate a data current from the power supplied from the power line and supply it to the first electrode 4.

The sensing thin film transistor is used to detect the threshold voltage deviation of the driving thin film transistor, which can lead to image quality deterioration. The sensing thin film transistor may apply the current from the driving thin film transistor to the reference line in response to a sensing control signal applied by the gate line or a separate sensing line.

The capacitor is used to maintain the data voltage applied to the driving thin film transistor for one frame period, and is connected to each of a gate terminal and a source terminal of the driving thin film transistor.

Each of the sub-pixels 21, 22, and 23 is defined by the crossing structure of the gate lines and the data lines. The insulating layer 3 may surround the circuit portions 31, 32, and 33.

The first circuit unit 31, the second circuit unit 32, and the third circuit unit 33 are arranged in the first insulating layer 3a for each of the individual sub-pixel 21, 22, and 23. The first circuit unit 31 is connected to the first electrode 4 arranged on the first sub-pixel 21 to apply a driving voltage for emitting light of a color corresponding to the first sub-pixel 21. The first circuit unit 31, the second circuit unit 32, and the third circuit unit 33 may be located on the same layer, but the embodiments of the disclosed technology are not limited thereto.

The second circuit unit 32 is connected to the first electrode 4 arranged on the second sub-pixel 22 to apply a driving voltage to emit light of a color corresponding to the second sub-pixel 22.

The third circuit unit 33 is connected to the first electrode 4 arranged on the third sub-pixel 23 to apply a driving voltage to emit light of a color corresponding to the third sub-pixel 23.

Each of the first sub-pixel 21, the second sub-pixel 22, and the third sub-pixel 23 applies a predetermined current to the light-emitting layer depending on the data voltage of the data line when a gate signal is input from the gate line using the respective circuit portions 31, 32, and 33. Therefore, the light-emitting layer of each of the first sub-pixel 21, the second sub-pixel 22, and the third sub-pixel 23 may emit light with a predetermined brightness depending on a predetermined current.

The insulating layer 3 may protect the circuit portions 31, 32, and 33. The insulating layer 3 may include an inorganic insulating material, but is not necessarily limited thereto, and may also include an organic insulating material. For example, the insulating layer 3 may include an inorganic material such as silicon nitride (SiNx), silicon oxide (SiOx), or aluminum oxide (Al2O3), but the embodiments of the disclosed technology are not limited thereto. The first insulating layer 3a, the second insulating layer (3b), the third insulating layer 3c, and the fourth insulating layer 3d may include inorganic materials such as silicon nitride (SiNx), silicon oxide (SiOx), or aluminum oxide (Al2O3), but the embodiments of the disclosed technology are not limited thereto.

A connecting electrode CE and a plurality of electrode patterns may be arranged on the insulating layer 3. The plurality of electrode patterns may include a connecting electrode CE on the first insulating layer 3a, a first electrode pattern 42a and 42a′ on the second insulating layer (3b), a second electrode pattern 42b and 42b′ on the third insulating layer 3c, and a third electrode pattern 42c and 42c′ on the fourth insulating layer 3d. The first electrode pattern 42a and 42a′ may include a first reflective electrode 42a and a first connecting electrode 42a′, the second electrode pattern 42b and 42b′ may include a second reflective electrode 42b and a second connecting electrode 42b′, and the third electrode pattern 42c and 42c′ may include a third reflective electrode 42c and a third connecting electrode 42c′.

The connection electrode CE may be arranged in each of the sub-pixels 21, 22, and 23. The connection electrodes (CE) are arranged in each of the first sub-pixel 21, the second sub-pixel 22, and the third sub-pixel 23, and may be arranged on the first insulating layer 3a. The connection electrodes CE of each of the sub-pixels 21, 22, and 23 may be electrically connected to each circuit unit 31, 32, and 33 through the first via (VIA). The first via VIA1 may include copper Cu or tungsten W, but the embodiments of the disclosed technology are not limited thereto. The first via VIA1 may be formed in a hole used to recesses the first insulating layer 3a in the thickness direction.

The first reflective electrode 42a and the first connection electrode 42a′ are arranged at the same height (e.g., on the same layer in a laminated structure) and may include the same material. The second reflective electrode 42b and the second connection electrode 42b′ are arranged at the same height (e.g., on the same layer in a laminated structure) and may include the same material. The third reflective electrode 42c and the third connection electrode 42c′ are arranged at the same height (e.g., on the same layer in a laminated structure) and may include the same material.

Each electrode pattern may include a reflective material for reflecting light. For example, the reflective material may be a metal, but is not necessarily limited thereto, and may be another type of material as long as it may reflect light. The material constituting each electrode pattern will be described later.

The reflective electrodes 42 (e.g., 42a, 42b, and 42c) are arranged at a relatively lower level than the common light-emitting layer 5 that emits light, such that the light emitted from the common light-emitting layer 5 may be reflected upward. Here, “upward” refers to a direction in which a user perceives the emitted light, and for example, toward the side where the sealing layer 8 or the color filter layer 9 is arranged. Accordingly, the first sub-pixel 21, the second sub-pixel 22, and the third sub-pixel 23 may exhibit improved light efficiency compared to a case where the reflective electrodes 42 (42a, 42b, and 42c) are not present. This improved light efficiency allows the user to perceive a high-brightness image, i.e., a clear image, through the improved light efficiency.

The first reflective electrode 42a is arranged on the second insulating layer 3b in the first sub-pixel 21, and the first connecting electrodes 42a′ may be arranged on the second insulating layer 3b in each of the sub-pixels 21, 22, and 23, and may be connected to the first reflective electrode 42a in the first sub-pixel 21. The first connecting electrodes 42a′ arranged in each of the sub-pixels 21, 22, and 23 may be electrically connected to the connecting electrode CE through the second via VIA2. The second via VIA2 may include copper (Cu) or tungsten (W), but the embodiments of the disclosed technology are not limited thereto. The second via VIA2 may be formed in a hole used to recess the second insulating layer 3b in the thickness direction.

To improve the efficiency of OLEDs, it is necessary to increase the reflectivity of the electrodes. However, when electrodes are arranged in multiple layers, the reflectivity of some of the electrodes can deteriorate due to thermal processes applied during different fabrication steps, depending on which layer they are positioned in. To address this issue, the disclosed technology can be implemented in some embodiments to vary the thickness of the electrodes according to their respective layers (i.e., their vertical position), thereby maximizing the overall reflectivity of the electrodes.

The first reflective electrode 42a is arranged in the first light-emitting area EA1 and may also be arranged in the first non-light-emitting area NEA1. In some embodiments of the disclosed technology, the first connection electrode 42a′ is arranged in the first non-light-emitting area NEA1 and a part thereof extends toward the first light-emitting area EA1, but the embodiments of the disclosed technology are not limited thereto, and the first connection electrode 42a′ may be arranged only in the first non-light-emitting area NEA1. The first electrode pattern 42a and 42a′ may have a first thickness t1.

A third insulating layer 3c may be arranged on the first reflective electrode 42a and the first connecting electrode 42a′.

The second reflective electrode 42b may be arranged on the third insulating layer 3c in the second sub-pixel 22, and the second connecting electrodes 42b′ may be arranged on the third insulating layer 3c in each of the sub-pixels 21, 22, and 23. The second connecting electrodes 42b′ arranged in each of the sub-pixels 21, 22, and 23 may be electrically connected to the first connecting electrode 42a′ below a first through-hole TH1. The third insulating layer 3c may be recessed in the first through-hole TH1 in the thickness direction. In the first sub-pixel 21, the second connection electrode 42b′ is electrically connected to the first connection electrode 42a′ via the first through-hole TH1; in the second sub-pixel 22, the second connection electrode 42b′ is electrically connected to the first connection electrode 42a′ via the first through-hole TH1; and in the third sub-pixel 23, the second connection electrode 42b′ may be electrically connected to the first connection electrode 42a′ via the first through-hole TH1. In FIG. 2, the first through-hole TH1 is illustrated as being arranged in the light-emitting area EA1, EA2, and EA3, but the first through-hole TH1 may also be arranged in the non-light-emitting area NEA1, NEA2, and NEA3. The second electrode pattern 42b and 42b′ may have a second thickness t2.

A fourth insulating layer 3d may be placed on the second reflective electrode 42b and the second connecting electrode 42b′.

The third reflective electrode 42c is arranged on the fourth insulating layer 3d in the third sub-pixel 23, and the third connecting electrodes 42c′ may be arranged on the fourth insulating layer 3d in each of the sub-pixels 21, 22, and 23. The third connecting electrodes 42c′ arranged in each of the sub-pixels 21, 22, and 23 may be electrically connected to the second connecting electrode 42b′ below the second through-hole TH2. The fourth insulating layer 3d may be recessed in the second through-hole TH2 in the thickness direction. In the first sub-pixel 21, the third connecting electrode 42c′ is electrically connected to the second connecting electrode 42b′ via the second through-hole TH2; in the second sub-pixel 22, the third connecting electrode 42c′ is electrically connected to the second connecting electrode 42b′ via the second through-hole TH2; and in the third sub-pixel 23, the third connecting electrode 42c′ may be electrically connected to the second connecting electrode 42b′ via the second through-hole TH2. In FIG. 2, the second through-hole TH2 is illustrated as being arranged in the light-emitting areas EA1, EA2, and EA3, but the second through-hole TH2 may also be arranged in the non-light-emitting areas NEA1, NEA2, and NEA3. The third electrode pattern 42c and 42c′ may have a third thickness t3.

Although not shown, a trench (not shown) may be formed in at least one insulating layer 3a, 3b, 3c, and 3d. For example, the trench may be formed in a non-emitting area NEA1, NEA2, and NEA3. For example, the trench may be formed to penetrate a part or all of the fourth insulating layer 3d, but the embodiments of the disclosed technology are not limited thereto. The trench may prevent lateral leakage current LLC between adjacent sub-pixels 21, 22, and 23 due to the common light-emitting layer 5.

As shown in FIG. 2, in the emitting areas EA1, EA2, and EA3, the distances between the respective reflective electrodes 42a, 42b, and 42c and the second electrode 6 may be different from each other. For example, the distance between the first reflective electrode 42a and the second electrode 6 may be the largest, then the distance between the second reflective electrode 42b and the second electrode 6 may be intermediate, and the distance between the third reflective electrode 42c and the second electrode 6 may be the smallest.

In this way, since the reflective electrodes 42a, 42b, and 42c are formed to have various distances (or resonance distances) from the second electrode 6, the light extraction efficiency of different colors may be improved through reflection and re-reflection between the reflective electrodes 42a, 42b, and 42c and the second electrode 6 depending on the distance. Therefore, the light extraction efficiency of red light may be improved in the first sub-pixel 21, the light extraction efficiency of green light may be improved in the second sub-pixel 22, and the light extraction efficiency of blue light may be improved in the third sub-pixel 23.

The anode electrode 41 may include the first anode electrode 41a of the first sub-pixel 21, the second anode electrode 41b of the second sub-pixel 22, and the third anode electrode 41c of the third sub-pixel 23. The anode electrodes 41a, 41b, and 41c are arranged in the same layer and may contain the same material.

The anode electrodes 41a, 41b, or 41c may be directly disposed on the third connection electrode 42c′ or the third reflective electrode 42c in the sub-pixels 21, 22, and 23, respectively. The anode electrodes 41a, 41b, and 41c may be electrically connected to the third connection electrode 42c′ or the third reflective electrode 42c in the sub-pixels 21, 22, and 23, respectively. The anode electrodes 41a, 41b, and 41c may be disposed in the light-emitting areas EA1, EA2, and EA3, respectively, and a part thereof may extend toward the non-light-emitting areas NEA1, NEA2, and NEA3.

The anode electrodes 41a, 41b, and 41c may include a material having high light transmittance. The anode electrode 41a, 41b, and 41c may be provided in a transparent form so that light reflected from the reflective electrode 42a, 42b, and 42c may travel upward. The anode electrode 41a, 41b, and 41c may be formed using a transparent material, but the disclosed technology is not limited thereto. In some implementations, the anode electrode 41a, 41b, and 41c may be formed using a metal material in the form of a thin film as long as it may transmit light. For example, the anode electrode 41a, 41b, and 41c may include TiN (titanium nitride), but the embodiments of the disclosed technology are not limited thereto. For example, when the anode electrode 41a, 41b, and 41c includes TiN, the thickness thereof may be about 5 nm or less. For example, the thickness of the anode electrode 41a, 41b, and 41c may be about 3 nm or less, but is not limited thereto. For example, the anode electrode 41a, 41b, and 41c may include a transparent conductive oxide such as ITO or IZO.

In some embodiments, a bank may be arranged on the anode electrode 41a, 41b, and 41c. The bank may be composed of multiple layers, but the embodiments of the disclosed technology are not limited thereto. For example, the bank may include three stacked banks BK.

The bank BK may include an inorganic material such as silicon nitride (SiNx), silicon oxide (SiOx), or aluminum oxide (Al2O3), but the embodiments of the disclosed technology are not limited thereto. The bank BK may include one or more layers, but the embodiments of the disclosed technology are not limited thereto.

The bank BK may be arranged on the non-emitting area NEA1, NEA2, and NEA3. In the emitting area EA1, EA2, and EA3, the bank BK may expose the upper surface of the anode electrode 41a, 41b, and 41c to define the emitting area EA1, EA2, and EA3.

The common light-emitting layer 5 is formed on the anode electrode 41a, 41b, and 41c and the bank BK. The common light-emitting layer 5 may be in contact with the upper surface of the anode electrode 41a, 41b, and 41c. The common light-emitting layer 5 may be in direct contact with the upper surface of the anode electrode 41a, 41b, and 41c, the upper surface and side surface of the bank BK, and the upper surface of the insulating layer 3.

An organic light-emitting device (OLED) based on an embodiment may include an anode electrode 41 (ANO) (or a first electrode 4), a second electrode 6 (CAT), and a common light-emitting layer 5 between the first electrode 4 and the second electrode 6.

The common light-emitting layer 5 may be provided to emit white (W) light. To this end, the common light-emitting layer 5 may be configured to include a plurality of stacks that emit light of different colors. Specifically, the common light-emitting layer 5 may be formed by including a first stack, a second stack, and a charge generation layer (CGL) provided between the first stack and the second stack.

The second electrode 6 is formed on the common light-emitting layer 5. The second electrode 6 may function as a cathode of the display panel 100. The second electrode 6 is formed on each sub-pixel 21, 22, and 23 and between them, similar to the common light-emitting layer 5.

In the display panel 100 based on an embodiment, the second electrode 6 may be formed as a translucent electrode to implement white light with light efficiency in a top emission method. Accordingly, a micro-cavity effect may be obtained for each of the first to third sub-pixels 21, 22, and 23. The micro-cavity effect may be obtained by repeating the reflection and re-reflection of light between the second electrode 6 and the reflective electrode 42, thereby improving the light extraction efficiency.

In some implementations, since the second electrode 6 is formed on the upper surface of the common light-emitting layer 5, it may be formed along the surface profile of the common light-emitting layer 5. The common light-emitting layer 5 is formed along the surface profile of the first electrode 4 in the light-emitting region, and, as a result, the second electrode 6 may be formed along the surface profile of the first electrode 4. In addition, a capping layer 7 may also be formed on the second electrode 6 along the surface profile of the second electrode 6.

The capping layer 7 may include an inorganic insulating material, but is not limited thereto. The capping layer 7 may be disposed on the second electrode 6 to protect the organic light-emitting element (OLED).

The sealing layer 8 is formed on the second electrode 6 to prevent external moisture from penetrating into the common light-emitting layer 5. The sealing layer 8 may include an inorganic insulating material or may have a structure in which inorganic insulating material and organic insulating material are alternately laminated, but is not necessarily limited thereto.

The color filter layer 9 is formed on the sealing layer 8. The color filter layer 9 may be configured to include, but is not necessarily limited to, a first color filter 91 of red (R) provided in the first sub-pixel 21, a second color filter 92 of green (G) provided in the second sub-pixel 22, and a third color filter 93 of blue (B) provided in the third sub-pixel 23. Although not shown, a black matrix may be provided between the first to third color filters 91, 92, and 93 to prevent color mixing between sub-pixels.

In some embodiments, a micro lens (ML) may be arranged on the color filter layer 9 to collect light incident from the outside. A plurality of micro lenses (ML) may be provided and arranged for each of the sub-pixels 21, 22, and 23.

A flattening layer 10 may be placed on the micro lens (ML), and a cover layer 20 may be placed on the flattening layer 10. The cover layer 20 may include glass or plastic, but the embodiments of the disclosed technology are not limited thereto.

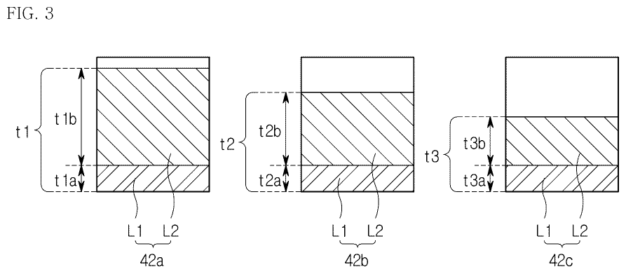

FIG. 3 is an enlarged view showing a first reflective electrode, a second reflective electrode, and a third reflective electrode, based on an embodiment. FIG. 3 illustrates only the first reflective electrode 42a, the second reflective electrode 42b, and the third reflective electrode 42c of FIG. 2, but the first connection electrode 42a′, the second connection electrode 42b′, and the third connection electrode 42c′ may also have the same thickness and structure as the first reflective electrode 42a, the second reflective electrode 42b, and the third reflective electrode 42c, respectively.

Referring to FIG. 3, the first reflective electrode 42a may have a first thickness t1, the second reflective electrode 42b may have a second thickness t2, and the third reflective electrode 42c may have a third thickness t3, based on an embodiment. The first thickness t1 may be greater than the second thickness t2 and the third thickness t3, and the second thickness t2 may be greater than the third thickness t3.

Each of the reflective electrodes 42a, 42b, and 42c may include a first layer L1 and a second layer L2 on the first layer L1. The first layer L1 and the second layer L2 may include different materials from each other. The first and second layers L1 and L2 may each include a metal material. For example, the first layer L1 may include titanium (Ti), and the second layer L2 may include aluminum (Al). The second layer L2 may include a material having better light reflectivity than the first layer L1.

As shown in FIG. 2, the first layer L1 may be in direct contact with each of the insulating layers 3b, 3c, and 3d. The first layer L1 may be a material required to deposit each of the reflective electrodes 42a, 42b, and 42c on each insulating layer 3b, 3c, and 3d. That is, since the second layer L2 (or aluminum (Al)) cannot be directly deposited on each insulating layer 3b, 3c, and 3d due to process reasons, the first layer L1 may be disposed before the second layer L2. In some embodiments, the first layer L1 may include titanium nitride (TiN), but the embodiments of the disclosed technology are not limited thereto. For example, the first layer L1 of each of the reflective electrodes 42a, 42b, and 42c may have a predetermined thickness t1a, t2a, and t3a. The range of the thickness t1a, t2a, and t3a of the first layer L1 of each of the reflective electrodes 42a, 42b, and 42c may be the same, but the embodiments of the disclosed technology are not limited thereto. For example, the respective thickness t1a, t2a, and t3a of the first layer L1 of the respective reflective electrodes 42a, 42b, and 42c may be about 10 nm to about 20 nm, but the embodiments of the disclosed technology are not limited thereto.

The thicknesses t1b, t2b, and t3b of the second layers L2 of each reflective electrode 42a, 42b, and 42c may be different from each other. For example, the thickness t1b of the second layer L2 of the first reflective electrode 42a may be greater than the thickness t2b of the second layer L2 of the second reflective electrode 42b and the thickness t3b of the second layer L2 of the third reflective electrode 42c, and the thickness t2b of the second layer L2 of the second reflective electrode 42b may be greater than the thickness t3b of the second layer L2 of the third reflective electrode 42c.

In an embodiment, the thickness t1b, t2b, and t3b of the second layer L2 of each reflective electrode 42a, 42b, and 42c is about 2 to 12 times the thickness t1a, t2a, and t3a of the first layer L1 of each reflective electrode 42a, 42b, and 42c, to achieve high reflectivity with respect to each of the reflective electrodes 42a, 42b, and 42c.

For example, when the thickness t1b, t2b, and t3b of the second layer L2 of each reflective electrode 42a, 42b, and 42c is less than about 2 times the thickness t1a, t2a, and t3a of the first layer L1 of each reflective electrode 42a, 42b, and 42c, it may be difficult to achieve the desired reflectivity of the reflective electrode 42a, 42b, and 42c. In contrast, when the thicknesses t1b, t2b, and t3b of the second layer L2 of the reflective electrodes 42a, 42b, and 42c exceed about 12 times the thickness t1a, t2a, and t3a of the first layer L1 of each reflective electrode 42a, 42b, and 42c, it may be difficult to grow the second layer L2 properly.

FIGS. 4 to 6 are cross-sectional views showing each of process steps in a manufacturing process of a display device, based on an embodiment.

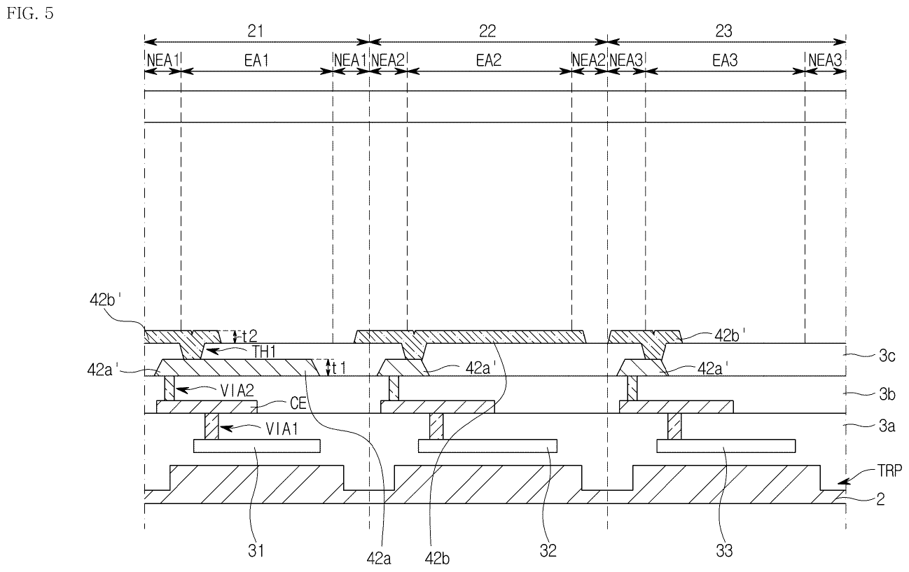

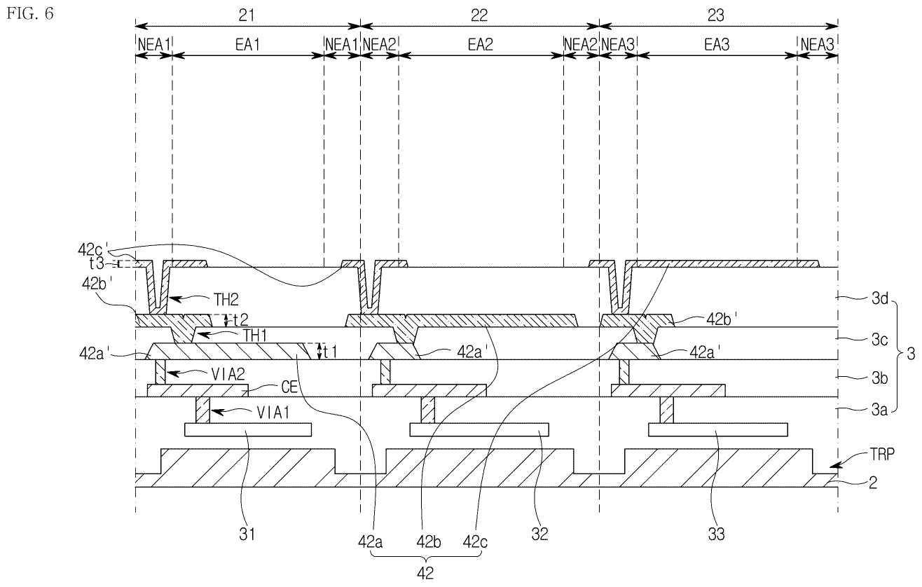

As shown in FIG. 4, the first electrode pattern 42a and 42a′ described in FIG. 2 is formed; and as shown in FIG. 5, the third insulating layer 3c and the second electrode pattern 42b and 42b′ are formed on the first electrode pattern 42a and 42a′ described in FIG. 2; and as shown in FIG. 6, the fourth insulating layer 3d and the third electrode pattern 42c and 42c′ described in FIG. 2 are formed.

That is, the first electrode pattern 42a and 42a′, the second electrode pattern 42b and 42b′, and the third electrode pattern 42c and 42c′ may be formed in different processes, and the first electrode pattern 42a and 42a′ may be formed first.

According to a manufacturing process based on an embodiment, the temperature of the post-process (or subsequent thermal process) used to form the second electrode pattern 42b and 42b′, the third electrode pattern 42c and 42c′, and the insulating layer 3c and 3d may be at most about 400 degrees Celsius.

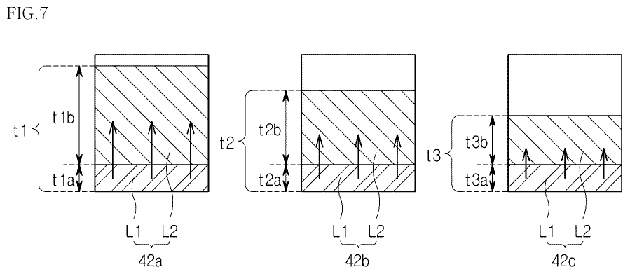

FIG. 7 is a drawing showing diffusion of titanium (Ti) due to a subsequent thermal process of a first reflective electrode, a second reflective electrode, and a third reflective electrode, based on an embodiment.

Referring to FIGS. 6 and 7, the first layer L1 of each of the reflective electrodes 42a, 42b, and 42c based on an embodiment may be diffused when heat of about 300 degrees Celsius or more is applied. That is, titanium (Ti) included in the first layer L1 may be diffused toward the second layer L2 when heat of about 300 degrees Celsius or more is applied.

For example, since the first reflective electrode 42a is exposed to the above-described high temperature (or high heat) for a longer time than the second reflective electrode 42b and the third reflective electrode 42c, the degree of diffusion of titanium (Ti) of the first reflective electrode 42a may be the greatest, the degree of diffusion of titanium (Ti) of the second reflective electrode 42b may be intermediate, and the degree of diffusion of titanium (Ti) of the third reflective electrode 42c may be the smallest. The diffused titanium (Ti) may react with aluminum (Al) of the second layer L2 to form titanium aluminum (TiAl3). The titanium (Ti) and aluminum (Al) alloy may have significantly lower light reflectance than aluminum (Al).

In the manufacturing process, when the thicknesses of the first reflective electrode, the second reflective electrode, and the third reflective electrode are the same (or the thicknesses of the second layers of each reflective electrode are the same), the thickness of the titanium aluminum (TiAl3) of the first reflective electrode may be greater than the thickness of the titanium aluminum (TiAl3) of the second reflective electrode and the thickness of the titanium aluminum (TiAl3) of the third reflective electrode after the subsequent thermal process is completed. In other words, the thickness of the second layer of the first reflective electrode may be the smallest after the subsequent thermal process is completed. As a result, not only the light reflectivity of the first reflective electrode is significantly lowered, but also the reflectivity of each of the first reflective electrode, the second reflective electrode, and the third reflective electrode may become uneven.

Herein, in the case of the display device based on an embodiment, the thickness may be designed and changed depending on the time of exposure to the subsequent thermal process. That is, the thickness t1 of the first reflective electrode 42a may be greater than the thickness t2 of the second reflective electrode 42b and the thickness t3 of the third reflective electrode 42c, and the thickness t2 of the second reflective electrode 42b may be greater than the thickness t3 of the third reflective electrode 42c.

In addition, the thickness t1b of the second layer L2 of the first reflective electrode 42a, which substantially has a light reflection function, is greater than the thickness t2b of the second layer L2 of the second reflective electrode 42b and the thickness t3b of the second layer L2 of the third reflective electrode 42c, and the thickness t2b of the second layer L2 of the second reflective electrode 42b may be greater than the thickness t3b of the second layer L2 of the third reflective electrode 42c.

Therefore, even if the substantial thickness of the second layer L2 is reduced due to diffusion of the first layer L1 into the second layer L2 in the subsequent thermal process, the decrease in the light reflectivity of the first reflective electrode 42a may be minimized.

In addition, considering the time of exposure to the subsequent thermal process, since the thickness t1b, t2b, and t3b of the second layer L2 of each reflective electrode 42a, 42b, and 42c is designed differently, there is an advantage in that the reflectivity of each reflective electrode 42a, 42b, and 42c may be maintained equally.

Hereinafter, a display device based on another embodiment will be described. For clarification, repeated descriptions or detailed explanations of drawing symbols and configurations already provided in FIGS. 1 to 7 will be omitted.

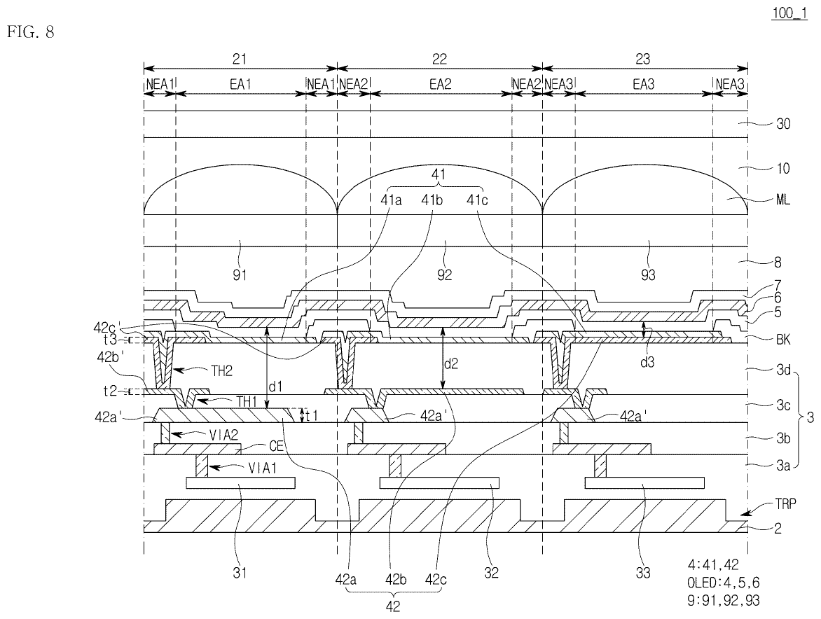

FIG. 8 is a cross-sectional view of a display panel based on another embodiment.

Referring to FIG. 8, in the display panel 100_1 based on some embodiments, the first reflective electrode 42a may have a first thickness t1, the second reflective electrode 42b may have a second thickness t2, and the third reflective electrode 42c may have a third thickness t3. The first thickness t1 may be greater than the second thickness t2 and the third thickness t3, and the second thickness t2 may be equal to the third thickness t3.

In the display panel 100_1 based on some embodiments, the first thickness t1 of the first reflective electrode 42a that is most exposed to the subsequent thermal process is higher, but the thicknesses t2 and t3 of the second reflective electrode 42b and the third reflective electrode 42c are designed to be lower than the first thickness t1 and the same as each other, which is different from the display panel 100 according to FIG. 2.

Since the other descriptions have been described above in FIG. 2, detailed descriptions will be omitted.

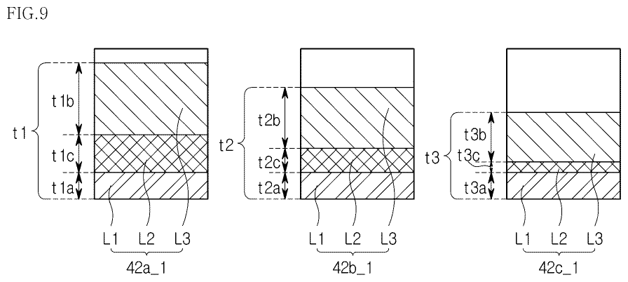

FIG. 9 is an enlarged view showing a first reflective electrode, a second reflective electrode, and a third reflective electrode, based on another embodiment.

Referring to FIG. 9, each reflective electrode 42a_1, 42b_1, and 42c_1 is different from the reflective electrode 42a, 42b, and 42c according to FIG. 3, in that it includes a third layer L3 between the first layer L1 and the second layer L2.

More specifically, the third layer L3 may include an alloy of the material of the first layer L1 and the material of the second layer L2. The third layer L3 may include, for example, titanium aluminum (TiAl3), but the embodiments of the disclosed technology are not limited thereto.

As described above in FIG. 7, after the subsequent thermal process is completed, the thickness t1c of the third layer L3 of the first reflective electrode 42a_1 may be greater than the thickness t2c of the third layer L3 of the second reflective electrode 42b_1 and the thickness t3c of the third layer L3 of the third reflective electrode 42c_1, and the thickness t2c of the third layer L3 of the second reflective electrode 42b_1 may be greater than the thickness t3c of the third layer L3 of the third reflective electrode 42c_1.

Other descriptions will be omitted as they have already been described in detail in FIG. 7.

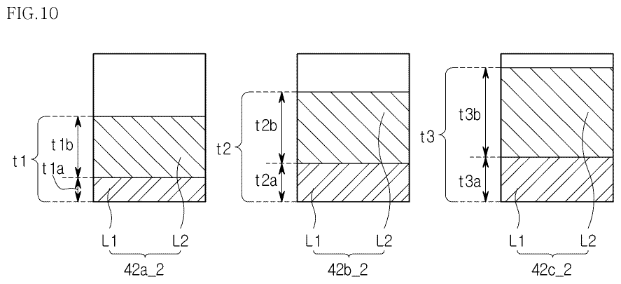

FIG. 10 is an enlarged view of the first reflective electrode, the second reflective electrode, and the third reflective electrode, according to another embodiment.

Referring to FIG. 10, the reflective electrodes 42a_2, 42b_2, and 42c_2 in the present embodiment are different from those in the embodiment referring to FIG. 3 in that the thicknesses of the first layers L1 may be different from each other.

In some implementations, the first reflective electrode 42a may have a first thickness t1, the second reflective electrode 42b may have a second thickness t2, and the third reflective electrode 42c may have a third thickness t3. The third thickness t3 may be greater than the first thickness t1 and the second thickness t2, and the second thickness t2 may be greater than the first thickness t1.

The thicknesses t1a, t2a, and t3a of the first layer L1 of each reflective electrode 42a_2, 42b_2, and 42c_2 may be different from each other. For example, the thickness t1a of the first layer L1 of the third reflective electrode 42c_2 may be greater than the thickness t1b of the first layer L1 of the second reflective electrode 42b_2 and the thickness t3a of the first layer L1 of the first reflective electrode 42a_2, and the thickness t2a of the first layer L1 of the second reflective electrode 42b_2 may be greater than the thickness t1a of the first layer L1 of the first reflective electrode 42a_2.

The thicknesses of the second layers L2 of each of the reflective electrodes 42a_2, 42b_2, and 42c_2 may be the same as each other.

In some embodiments, since the thickness t1a of the first layer L1 of the third reflective electrode 42c_2 is greater than the thickness t1b of the first layer L1 of the second reflective electrode 42b_2 and the thickness t3a of the first layer L1 of the first reflective electrode 42a_2, and the thickness t2a of the first layer L1 of the second reflective electrode 42b_2 is greater than the thickness t1a of the first layer L1 of the first reflective electrode 42a_2, there is an advantage that diffusion of the material (titanium (Ti)) of the first layer L1 of the first reflective electrode 42a_2 due to the subsequent thermal process may be minimized.

The display device based on various embodiments of the disclosed technology may be described as follows.

In various embodiments of the present disclosure, a display device comprises a substrate including pixel regions for a plurality of sub-pixels configured to emit light in response to an electric signal (e.g., a current), wherein the plurality of sub-pixels include a first sub-pixel, a second sub-pixel, and a third sub-pixel; a first reflective electrode disposed on the substrate in the first sub-pixel; a first insulating layer disposed on the first reflective electrode; a second reflective electrode disposed on the first insulating layer in the second sub-pixel; a second insulating layer disposed on the second reflective electrode; and a third reflective electrode disposed on the second insulating layer in the third sub-pixel, wherein the thickness of the first reflective electrode is greater than the thickness of the second reflective electrode and the thickness of the third reflective electrode.

The thickness of the second reflective electrode may be greater than the thickness of the third reflective electrode.

Each of the first reflective electrode, the second reflective electrode, and the third reflective electrode may include a first layer and a second layer on the first layer.

The first layer may include titanium (Ti), and the second layer may include aluminum (Al).

The thickness of the second layer may be greater than the thickness of the first layer.

The thickness of the second layer may be about twice or more the thickness of the first layer.

The thickness of the second layer of the first reflective electrode may be greater than the thickness of the second layer of the second reflective electrode and the thickness of the second layer of the third reflective electrode, respectively.

The thickness of the second layer of the second reflective electrode may be greater than the thickness of the second layer of the third reflective electrode.

The first reflective electrode, the second reflective electrode, and the third reflective electrode may each further include a third layer between the first layer and the second layer.

The thickness of the third layer of the first reflective electrode may be greater than the thickness of the third layer of the second reflective electrode and the thickness of the third layer of the third reflective electrode.

The thickness of the third layer of the second reflective electrode may be greater than the thickness of the third layer of the third reflective electrode.

The third layer may include a material of the first layer and a material of the second layer.

The third layer may include titanium aluminum (TiAl3).

The display device may further include circuit portions between the substrate and the first reflective electrode, and a first connecting electrode of the same layer as the first reflective electrode, wherein in each sub-pixel, the first connecting electrode may be electrically connected to the circuit portions.

The display device may further include a second connecting electrode of the same layer as the second reflective electrode, wherein in each sub-pixel, the second connecting electrode may be electrically connected to the first connecting electrode.

The display device may further include a third connecting electrode of the same layer as the third reflective electrode, wherein in each sub-pixel, the third connecting electrode may be electrically connected to the second connecting electrode.

In some embodiments, a display device may include a substrate including pixel regions for a plurality of sub-pixels configured to emit light in response to an electric signal (e.g., a current), wherein the plurality of sub-pixels include a first sub-pixel, a second sub-pixel, and a third sub-pixel; a first reflective electrode disposed on the first sub-pixel; a second reflective electrode disposed on the second sub-pixel; a third reflective electrode disposed on the third sub-pixel; an anode electrode disposed on the first reflective electrode, the second reflective electrode, and the third reflective electrode; a common light-emitting layer disposed on the anode electrode; and a cathode electrode disposed on the common light-emitting layer, wherein a distance between the first reflective electrode and the cathode electrode, a distance between the second reflective electrode and the cathode electrode, and a distance between the third reflective electrode and the cathode electrode are different from each other, and at least one of the first reflective electrode, the second reflective electrode, and the third reflective electrode has a different thickness than one or more remaining reflective electrodes.

The distance between the first reflective electrode and the cathode electrode is greater than the distance between the second reflective electrode and the cathode electrode, and the distance between the third reflective electrode and the cathode electrode, and the distance between the second reflective electrode and the cathode electrode is greater than the distance between the third reflective electrode and the cathode electrode, and the thickness of the first reflective electrode may be greater than the thickness of the second reflective electrode.

The thickness of the second reflective electrode may be greater than the thickness of the third reflective electrode.

The first reflective electrode, the second reflective electrode, and the third reflective electrode include each a first layer and a second layer on the first layer, and the thickness of the second layer may be greater than the thickness of the first layer, and the thickness of the second layer of the first reflective electrode may be greater than the thickness of the second layer of the second reflective electrode and the thickness of the second layer of the third reflective electrode.

Only a few implementations and examples are described and other implementations, enhancements and variations can be made based on what is described and illustrated in this patent document.

1. A display device, comprising:
a substrate including pixel regions for a plurality of sub-pixels configured to emit light in response to an electric signal, wherein the plurality of sub-pixels include a first sub-pixel, a second sub-pixel, and a third sub-pixel;
a first reflective electrode disposed on the substrate in the first sub-pixel;
a first insulating layer disposed on the first reflective electrode;
a second reflective electrode disposed on the first insulating layer in the second sub-pixel;
a second insulating layer disposed on the second reflective electrode; and
a third reflective electrode disposed on the second insulating layer in the third sub-pixel,
wherein a thickness of the first reflective electrode is greater than a thickness of the second reflective electrode and a thickness of the third reflective electrode.

2. The display device of claim 1, wherein the thickness of the second reflective electrode is greater than the thickness of the third reflective electrode.

3. The display device of claim 1, wherein each of the first reflective electrode, the second reflective electrode, and the third reflective electrode includes a first layer and a second layer on the first layer.

4. The display device of claim 3, wherein the first layer comprises titanium (Ti), and the second layer comprises aluminum (Al).

5. The display device of claim 3, wherein the thickness of the second layer is greater than the thickness of the first layer.

6. The display device of claim 5, wherein the thickness of the second layer is in a range of 2 to 12 times the thickness of the first layer.

7. The display device of claim 3, wherein the thickness of the second layer of the first reflective electrode is greater than the thickness of the second layer of the second reflective electrode and the thickness of the second layer of the third reflective electrode.

8. The display device of claim 7, wherein the thickness of the second layer of the second reflective electrode is greater than the thickness of the second layer of the third reflective electrode.

9. The display device of claim 3, wherein each of the first reflective electrode, the second reflective electrode, and the third reflective electrode further includes a third layer disposed between the first layer and the second layer.

10. The display device of claim 9, wherein the thickness of the third layer of the first reflective electrode is greater than the thickness of the third layer of the second reflective electrode and the thickness of the third layer of the third reflective electrode.

11. The display device of claim 10, wherein the thickness of the third layer of the second reflective electrode is greater than the thickness of the third layer of the third reflective electrode.

12. The display device of claim 9, wherein the third layer comprises a combination of a material of the first layer and a material of the second layer.

13. The display device of claim 9, wherein the third layer comprises titanium aluminum (TiAl₃).

14. The display device of claim 1, further comprising:
a circuit portion disposed between the substrate and the first reflective electrode, and a first connecting electrode disposed on a same layer as the first reflective electrode,
wherein in each sub-pixel, the first connecting electrode is electrically connected to the circuit portion.

15. The display device of claim 14, further comprising:
a second connecting electrode disposed on a same layer as the second reflective electrode,
wherein in each sub-pixel, the second connecting electrode is electrically connected to the first connecting electrode.

16. The display device of claim 15, further comprising:
a third connecting electrode disposed in a same layer as the third reflective electrode,
wherein in each sub-pixel, the third connecting electrode is electrically connected to the second connecting electrode.

17. A display device, comprising:
a substrate including pixel regions for a plurality of sub-pixels configured to emit light in response to an electric signal, wherein the plurality of sub-pixels include a first sub-pixel, a second sub-pixel, and a third sub-pixel;
a first reflective electrode disposed on the first sub-pixel;
a second reflective electrode disposed on the second sub-pixel;
a third reflective electrode disposed on the third sub-pixel;
an anode electrode disposed on the first reflective electrode, the second reflective electrode, and the third reflective electrode;
a common light-emitting layer disposed on the anode electrode; and
a cathode electrode disposed on the common light-emitting layer,
wherein a distance between the first reflective electrode and the cathode electrode, a distance between the second reflective electrode and the cathode electrode, and a distance between the third reflective electrode and the cathode electrode are different from each other, and
at least one of the first reflective electrode, the second reflective electrode, and the third reflective electrode has a different thickness than one or more remaining reflective electrodes.

18. The display device of claim 17, wherein the distance between the first reflective electrode and the cathode electrode is greater than the distance between the second reflective electrode and the cathode electrode, and the distance between the third reflective electrode and the cathode electrode, the distance between the second reflective electrode and the cathode electrode is greater than the distance between the third reflective electrode and the cathode electrode, a thickness of the first reflective electrode is greater than a thickness of the second reflective electrode, and the thickness of the second reflective electrode is greater than a thickness of the third reflective electrode.

19. A display device, comprising:
a substrate including pixel regions for a plurality of sub-pixels configured to emit light in response to an electric signal, wherein the plurality of sub-pixels include a first sub-pixel, a second sub-pixel, and a third sub-pixel;
a first reflective electrode disposed on the substrate in the first sub-pixel;
a first insulating layer disposed on the first reflective electrode;
a second reflective electrode disposed on the first insulating layer in the second sub-pixel;
a second insulating layer disposed on the second reflective electrode; and
a third reflective electrode disposed on the second insulating layer in the third sub-pixel,
wherein a thickness of the third reflective electrode is greater than a thickness of the second reflective electrode and a thickness of the first reflective electrode.

20. The display device of claim 19, wherein each of the first reflective electrode, the second reflective electrode, and the third reflective electrode includes a first layer and a second layer on the first layer; and
the thickness of the first layer of the first reflective electrode is smaller than the thickness of the first layer of the second reflective electrode and the thickness of the first layer of the third reflective electrode.
